(19) United States
(12) Patent Application Publication
(10) Pub. No.: US 2017/0004984 A1
(43) Pub. Date: Jan. 5, 2017

(54) SUBSTRATE TRANSFER APPARATUS AND SUBSTRATE TRANSFER METHOD

(71) Applicant: Tokyo Electron Limited, Tokyo (JP)

(72) Inventors: Hiroshi NAGAIKE, Miyagi (JP); Takamitsu TAKAYAMA, Miyagi (JP)

(21) Appl. No.: 15/185,254

(22) Filed: Jun. 17, 2016

(30) Foreign Application Priority Data
Jun. 30, 2015 (JP) 2015-131502

(51) Int. Cl. H01L 21/677; B08B 9/00

(52) U.S. Cl. CPC H01L 21/67739; B08B 9/00

(57) ABSTRACT

A substrate transfer apparatus includes a transfer chamber in which a substrate is transferred, and a process chamber configured to process a substrate therein. A contamination monitor is provided in the transfer chamber and configured to detect a contamination condition of the transfer chamber.

### CROSS-REFERENCE TO RELATED APPLICATIONS

This patent application is based upon and claims the benefit of priority of Japanese Patent Application No. 2015-131502, filed on Jun. 30, 2015, the entire contents of which are incorporated herein by reference.

### BACKGROUND OF THE INVENTION

1. Field of the Invention

The present invention relates to a substrate transfer apparatus and a substrate transfer method.

2. Description of the Related Art

A semiconductor manufacturing apparatus performs a predetermined process on a substrate by action of a gas. While processing the substrate, a reaction product is produced, attached to a wall surface and the like of a process chamber, and deposited thereon. When the reaction product peels off from the wall surface and the like and spreads over the substrate, it becomes a particle, which causes a defect in a product.

Therefore, as described in Japanese Laid-Open Patent Application Publication No. 2013-57658, Japanese Laid-Open Patent Application Publication No. 9-171992, and Japanese Laid-Open Patent Application Publication No. 2006-5118, a method of measuring a deposition amount of the reaction product by providing a sensor to sense minute accretion using a crystal oscillation in the process chamber, is proposed. This makes it possible to understand a change of an environment inside the process chamber in real time based on the measurement result. Moreover, it is possible to optimize conditions inside the process chamber and to make the environment inside the process chamber preferable before the conditions inside the process chamber become worse and the defects are caused in the product.

When transferring a processed substrate, a gas inside the process chamber diffuses into an adjacent transfer chamber. Thus, the reaction product is gradually deposited inside the transfer chamber. However, in the methods described in Japanese Laid-Open Patent Application Publication No. 2013-57658, Japanese Laid-Open Patent Application Publication No. 9-171992, and Japanese Laid-Open Patent Application Publication No. 2006-5118, because the sensor is provided inside the process chamber, it is difficult to measure the deposit amount of the reaction product inside the transfer chamber.

To solve this, determining the deposit amount of the reaction product inside the transfer chamber by visual inspection is considered. However, because a smaller amount of reaction product is gradually deposited over time in the transfer chamber than in the process chamber, visually inspecting the deposit amount of the reaction product in a short time is difficult. More specifically, it takes at least a week or two before sufficient reaction product is deposited to be noticeable upon a visual inspection. Due to this, the determination by visual inspection in a short time may cause an erroneous determination. Otherwise, if a lot of time is spent on the determination, the conditions inside the transfer chamber become worse until the end of the determination, thereby generating defects in a product while transferring the substrate.

### SUMMARY OF THE INVENTION

Accordingly, in view of the above discussed problems, embodiments of the present invention aim to provide a substrate transfer apparatus and a substrate transfer method that can form a preferable environment in a substrate transfer apparatus.

According to one embodiment of the present invention, there is provided a substrate transfer apparatus that includes a transfer chamber in which a substrate is transferred and a process chamber configured to process a substrate therein. A contamination monitor is provided in the transfer chamber and configured to detect a contamination condition of the transfer chamber.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are simply illustrative examples and are not restrictive of the invention as claimed.

### BRIEF DESCRIPTION OF THE DRAWINGS

FIGS. 1A through 1D are diagrams illustrating an example of a schematic configuration of a semiconductor manufacturing apparatus according to an embodiment of the present invention;

FIG. 2 is a diagram illustrating an example of an internal structure of a substrate transfer apparatus according to an embodiment of the present invention;

FIG. 3 is a flowchart illustrating an example of a substrate transfer process according to an embodiment of the present invention;

FIGS. 4A and 4B are diagrams illustrating examples of measurement results of a QCM according to an embodiment of the present invention;

FIGS. 5A through 5D are diagrams illustrating examples of changes in transfer conditions depending on measurement results of a QCM according to an embodiment of the present invention;

FIG. 6 is a diagram illustrating examples of changes in transfer conditions depending on measurement results of a QCM according to an embodiment of the present invention;

FIG. 7 is a flowchart of an example of an end point detection process of a cleaning according to an embodiment of the present invention; and

FIG. 8 is a diagram illustrating another example of a contamination monitor according to an embodiment of the present invention.

### DETAILED DESCRIPTION OF THE PREFERRED EMBODIMENTS

Embodiments of the present invention are described below, with reference to accompanying drawings. Note that elements having substantially the same functions or features may be given the same reference numerals and overlapping descriptions thereof may be omitted.

[Overall Configuration of Semiconductor Manufacturing Apparatus]

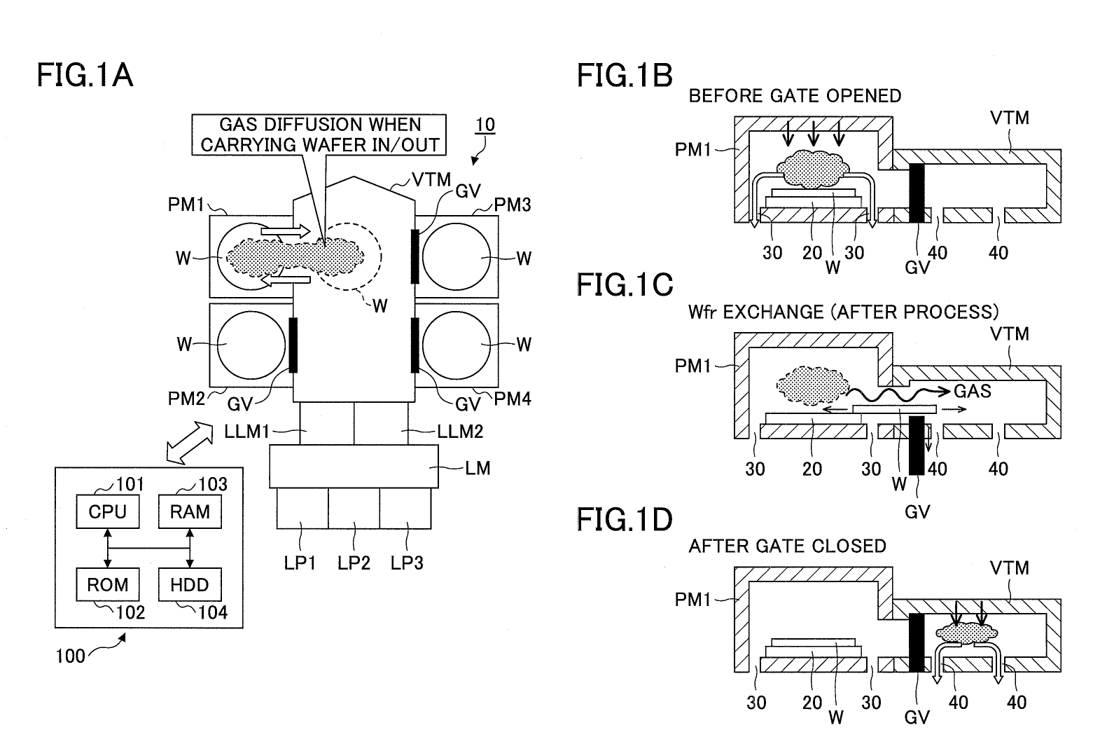

First, an example of an overall configuration of a semiconductor manufacturing apparatus 10 according to an embodiment of the present invention, is described below with reference to FIG. 1A. The semiconductor manufacturing apparatus illustrated in FIG. 1A is a cluster structured (multi-chamber type) system.

The semiconductor manufacturing apparatus 10 in FIG. 1A includes process modules PM1 through PM4, a vacuum transfer module VTM, load lock modules LLM1 and LLM2, a loader module LM, load ports LP1 through LP3, and a control unit 100. In the process module PM, a desired process is performed on a semiconductor wafer W (which may be hereinafter referred to as a “wafer W”).

The process modules PM1 through PM4 are arranged adjacent to the vacuum transfer module VTM. The process modules PM1 through PM4 are in communication with the vacuum transfer module VTM by opening/closing a gate valve GV. The process modules PMI through PM4 are evacuated up to a predetermined vacuum environment (pressure), and a process such as an etching process, a film deposition process, a cleaning process, or an ashing process, is performed therein.

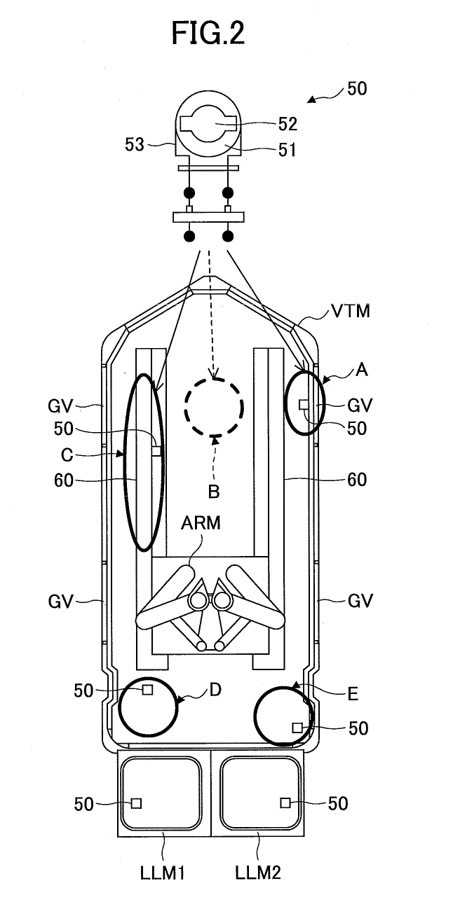

As illustrated in FIG. 2, a transfer device ARM for transferring a wafer W is disposed inside the vacuum transfer module VTM. The transfer device ARM includes two robot arms that are bendable and extendable and rotatable. Each of the robot arms has a hand capable of holding a wafer W at its tip. The transfer device ARM carries a wafer W into/out of the process modules PM1 through PM4 from/to the vacuum transfer module VTM in response to the opening and closing of the gate valve GV. Moreover, the transfer device ARM carries the wafer W into/out of the load lock modules LLM1 and LLM2.

FIG. 1A is described below again. The load lock modules LLM1 and LLM2 are provided between the vacuum transfer module VTM and the loader module LM. The load lock modules LLM1 and LLM2 transfer the wafer W from the loader module LM in the atmospheric environment to the vacuum transfer module VTM in the vacuum environment or from the vacuum transfer module VTM in the vacuum environment to the loader module LM in the atmospheric environment by being switched between the atmospheric environment and the vacuum environment.

The load ports LP1 through LP3 are provided along a side wall of a long side of the loader module LM. A FOUP (Front Opening Unified Pod) containing, for example, 25 wafers or an empty FOUP is installed in the load ports LP1 through LP3. The loader module LM carries the wafers W carried out of the FOUP installed in the load ports LP1 through LP3 into either the load lock module LLM1 or LLM2. Moreover, the loader module LM carries the wafers W carried out of either the load lock module LLM1 or LLM2 into the FOUP

A control unit 100 includes a CPU (Central Processing Unit) 101, a ROM (Read Only Memory) 102, a RAM (Random Access Memory) 103, and an HDD (Hard Disk Drive) 104. The control unit 100 may include not only the HDD 104 but also another memory area such as SSD (Solid State Drive). The memory area such as the HDD 104 and the RAM 103 stores a recipe specifying a process sequence, process conditions, and transfer conditions.

The CPU 101 controls a process of the wafer W at each process module PM and a transfer of wafer in accordance with the recipe. The HDD 104 and/or the ROM 103 may store a program for executing a substrate transfer process or a cleaning process described later. The program for executing the substrate transfer process or the cleaning process may be stored in a storage medium or from an external device through a network.

The number of process modules PM, vacuum transfer modules VTM, load lock modules LLM, and load ports LP are not limited to the number illustrated in the embodiment, but may be any number. The vacuum transfer module VTM, the load lock module LLM and the loader module LM are examples of a transfer chamber. In particular, the vacuum transfer module VTM is an example of a first transfer chamber adjacent to the process modules PM1 through PM4. The load lock module LLM and the loader module LM are examples of a second transfer chamber that is not adjacent to the process modules PM1 through PM4. As described below, a contamination monitor is installed in the vacuum transfer module VTM. At least one contamination monitor is installed in the vacuum transfer module VTM.

[Transfer of Wafer W]

Next, transfer of a wafer W and diffusion of a gas are described below. First, a wafer W is carried out of any of the load ports LP1 through LP3, and is carried into any of the process modules PM1 through PM4. More specifically, the wafer W is carried out of any of the load ports LP1 through LP3, and is carried into either the load lock module LLM1 or LLM2 by way of the loader module LM. In either the load lock module LLM1 or LLM2, into which the wafer W is carried, an exhaust treatment (evacuation) is performed and the inside is switched from the atmospheric environment to a vacuum environment. In this state, the wafer W is carried out of either the load lock module LLM1 or the load lock module LLM2 by the transfer device ARM and is carried into any of the process modules PM1 through PM4, where processing the wafer W is started. The inside of either the load lock module LLM1 or the load lock module LLM2, from which the wafer W is carried out, is switched from the vacuum environment to the atmospheric environment.

For example, an example of carrying the wafer W into the process module LM1 and performing a plasma etching process, is described below. An example of process conditions in this case is as follows.

<Process Conditions>

Gas: CF₄ (carbon tetrafluoride), C₄F₈ (perfluorocyclobutane), Ar (argon), N₂ (nitrogen), H₂ (hydrogen), O₂ (oxygen), and CO₂ (carbon dioxide)
Pressure: 10 mT (1.333 Pa) through 50 mT (6.666 Pa)
Process Time: about five minutes every time one wafer is processed.

Plasma is generated from a gas in the process module PM1, and a wafer W placed on the pedestal 20 of the process module PM1 is processed by action of the plasma. After processing the wafer W, as illustrated in FIG. 1B, the inside of the process module PM1 is purged by N₂ gas. N₂ gas is evacuated from exhaust openings 30.

After that, as illustrated in FIG. 1C, the gate valve is opened, and the processed wafer W is carried out of the process module PM1 and into the vacuum transfer module VTM. Moreover, an unprocessed wafer W is carried into the process module PM1. While transferring the wafer W, the gas inside the process module PM1 is diffused into the vacuum transfer module VTM adjacent to the process module PM1. Furthermore, the gas is released from the wafer W carried into the vacuum transfer module.

As illustrated in FIG. 10, after the gate valve GV is closed, the inside of the vacuum transfer module VTM is purged by N₂ gas. N₂ gas is evacuated from exhaust ports 40. In response to this, the gas diffused from the process module PM1 and the out gas released from the wafer W are evacuated from the exhaust ports 40. However, part of the gases remains inside the vacuum transfer module VTM. Due to this, a reaction product is gradually deposited inside the vacuum transfer module VTM.

At this time, a smaller amount of reaction product is gradually deposited over time in the vacuum transfer module VTM than in the vacuum transfer module VTM. Thus, in the vacuum transfer module VTM, it is difficult to visually check a deposition amount of the reaction product for a short time.

In contrast, the substrate transfer method according to the embodiment can determine a state of deposition of the reaction product in the vacuum transfer module VTM in a short time. For example, in the substrate transfer method according to the embodiment, the deposition state of the reaction product can be measured by using a QCM 50 provided in the vacuum transfer module VTM while processing about five wafers W in the process module PM, and transfer conditions can be optimized depending on the measurement result. This can prevent the reaction product in the vacuum transfer module VTM from attaching to the wafer W and then from becoming particles that cause defects in products while transferring the wafer W.

The processed wafer W is held by the transfer device ARM, and is carried into either the load lock module LLM1 or LLM2 In either the load lock module LLM1 or LLM2, an air supply process is performed, and the inside of either the load lock module LLM1 or LLM2 is switched from the vacuum environment to the atmospheric environment. In this state, the wafer W is taken out of any of the load lock module LLM1 and LLM2, and is transferred to the load port LP.

[Inside of Vacuum Transfer Module VTM]

Next, a contamination monitor disposed inside the vacuum transfer module VTM is described below with reference to FIG. 2. A QCM (Quartz Crystal Microbalance) 50 is provided within the vacuum transfer module VTM. The QCM 50 is an example of the contamination monitor that detects contamination conditions of the vacuum transfer module VTM.

The QCM 50 may be provided at the gate valve GV provided at the vacuum transfer module VTM (see A in FIG. 2). The QCM 50 may be provided at a ceiling portion of the vacuum transfer module VTM (see B in FIG. 2). The QCM 50 may be provided at a movable part of the transfer device ARM provided in the vacuum transfer module VTM (e.g., in the vicinity of a slide cover 60 on which the transfer device ARM slides, see D in FIG. 2). The QCM 50 may be provided at a corner portion of the vacuum transfer module VTM (see E in FIG. 2).

At least one QCM 50 may be disposed at any portion of the above-mentioned portions provided in the vacuum transfer module VTM. However, a plurality of QCMs 50 is preferably provided at the above-mentioned portions. By arranging the plurality of QCMs 50, the areas of the vacuum transfer module that are contaminated and the cause of deposited reaction product can be easily determined.

A principle of the QCM 50 is briefly described below. The QCM 50 is configured to include a crystal oscillator that includes a crystal plate 51 sandwiched between two electrodes 52, and the crystal oscillator is supported by a support 53. When a reaction product attaches to a surface of the crystal oscillator of the QCM 50, the following resonant frequency f of the QCM 50 varies depending on mass of the reaction product.

f=1/2t(\sqrt{C}/ρ)

Here, the letters of the above formula express as follows. t: thickness of the crystal plate, C: elastic constant, and ρ: density.

By utilizing this phenomenon, a small amount of accretion can be quantitatively measured depending on an amount of change of the resonant frequency f. The change of the resonant frequency f can be determined depending on a change of the elastic constant of the material attached to the crystal oscillator and a dimension of a thickness obtained by converting the accretion thickness of the attached material to a crystal density. By doing this, the change of the resonant frequency can be converted to the mass of the accretion.

By utilizing such a principle, the QCM 50 outputs a detection value indicating the resonant frequency. The detection value output from the QCM 50 is input to the control unit 100, and the control unit 100 calculates a film thickness and a film deposition rate by converting the change in frequency to the weight of the accretion. The control unit 100 controls transfer conditions of the wafer W in the vacuum transfer module VTM depending on the calculated film thickness or the film deposition rate, and transfers the wafer W based on the transfer conditions. Moreover, the control unit 100 properly controls a cleaning process depending on the calculated film thickness or the film deposition rate. Here, the film thickness or the film deposition rate calculated by the control unit 100 is an example of information indicating the contamination conditions of the vacuum transfer module.

The QCM 50 may be provided not only in the vacuum transfer module VTM but also in at least one of the load lock modules LLM1 and LLM2 and the loader module LM. This is because the out gas released from the wafer W is deposited on the load lock modules LLM1 and LLM2 and the loader module LM as the reaction product. At this time, the control unit 100 may control the transfer conditions of the wafer W and the like in the load lock modules LLM1 and LLM2 and the loader module LM depending on the information indicating the contamination conditions such as the film thickness or the film deposition rate detected by the QCM 50 in the load lock modules LLM1, LLM2 and/or the loader module LM.

When the QCM 50 is provided in the load lock modules LLM1 and/or LLM2, the QCM 50 is preferably arranged near an exhaust port provided in the load lock modules LLM1 and LLM2. Moreover, the QCM 50 is preferably arranged at a position where the wafer stays for a long time inside the loader module LM, the load lock module LLM1, LLM2 and/or the vacuum transfer module VTM.

[Substrate Transfer Process]

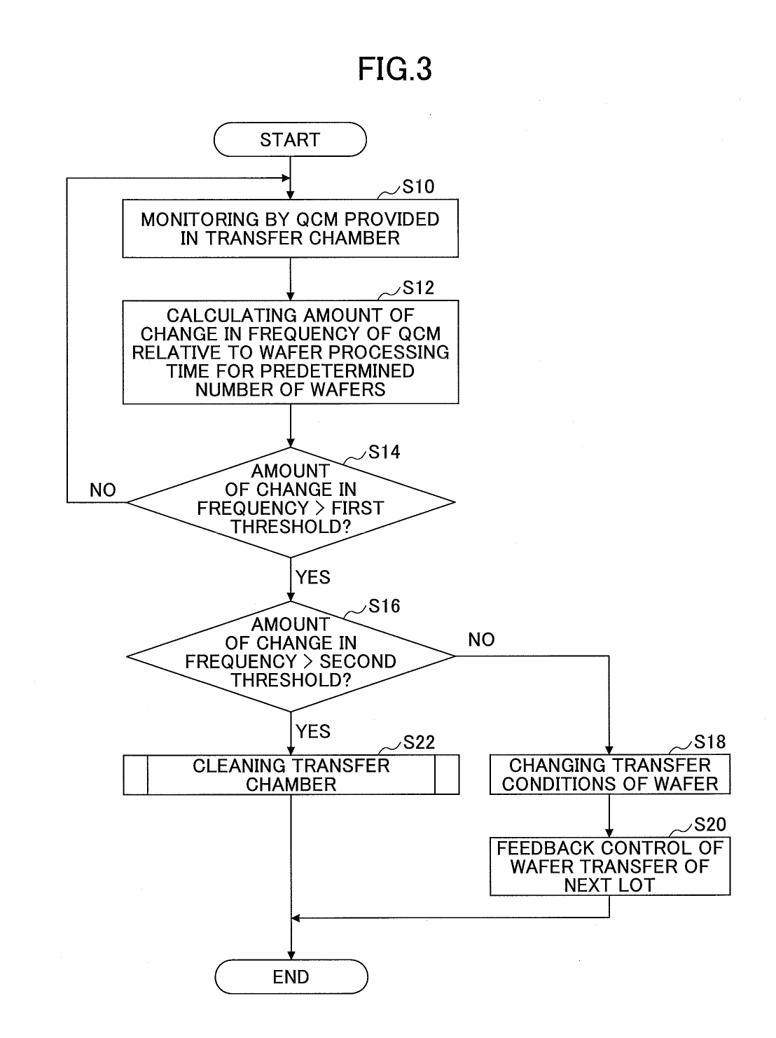

Next, an example of a substrate transfer process according to an embodiment is described below with reference to FIG. 3. The present process is controlled by the control unit 100. When the present process is started, the control unit 100 starts monitoring accretion by using the QCM 50 (crystal oscillator) disposed in the vacuum transfer module VTM (step S10). When a plurality of QCMs 50 is disposed in the vacuum transfer module VTM each of the plurality of QCMs 50 starts monitoring the secretion.

Subsequently, the control unit 100 calculates an amount of change in frequency of the crystal oscillator for processing time of a predetermined number of wafers W (step S12). The processing time of the predetermined number of wafers W may be set at a period when five to ten wafers W are processed.

Next, the control unit 100 determines whether the amount of change in frequency of the crystal oscillator exceeds a predetermined fist threshold (step S14). When the control unit 100 determines that the amount of change in frequency of the crystal oscillator is less than or equal to the first threshold, the process returns to step S10, and the processes from steps S10 through S14 are repeated.

When the control unit 100 determines that the amount of change in frequency of the crystal oscillator is greater than the first predetermined threshold, the control unit 100 determines whether the amount of change in frequency of the crystal oscillator is greater than a predetermined second threshold (step S16). The second threshold is set to a value greater than the first threshold.

When the control unit 100 determines that the amount of change in frequency of the crystal oscillator is less than or equal to the second threshold, the control unit 100 changes the transfer conditions of the wafer W (step S16). The control unit 100 controls, for example, at least one of conditions including a pressure of the vacuum transfer module VTM, a flow rate of an inert gas (N₂, Ar and the like) of the vacuum transfer module VTM, a pressure of the process modules PM1 through PM4, and a flow rate of an inert gas (N₂, Ar and the like) of the process modules PM1 through PM4.

Then, the control unit 100 adjusts the conditions in the vacuum transfer module VTM based on the changed transfer conditions, performs feedback control for controlling wafers W of the next lot (step S20), and finishes the present process.

On the other hand, in step S16, when the control unit 100 determines that the amount of change in frequency of the crystal oscillator exceeds the second threshold, the control unit 100 performs a cleaning process of the vacuum transfer module VTM (step S22), and finishes the present process.

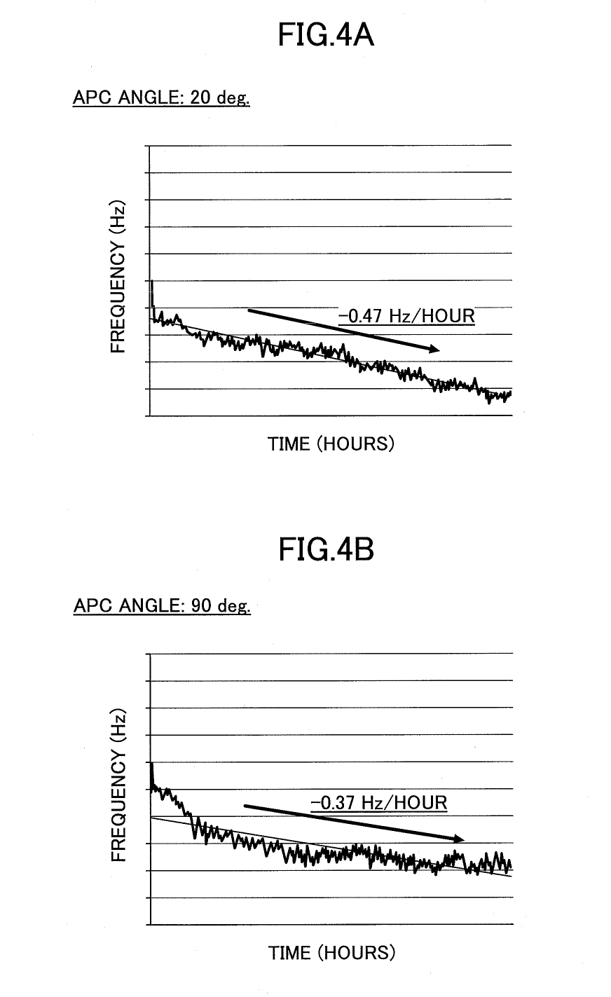

As described above, according to the substrate transfer process of the embodiment, when the amount of change in frequency of the crystal oscillator exceeds the first threshold and is less than or equal to the second threshold, the transfer conditions of the wafer W is changed. FIGS. 4A and 4B illustrate examples of a frequency of the crystal oscillator. The vertical axis in each graph shows a frequency of the QCM 50, and the horizontal axis shows time.

FIG. 4A illustrates an example of a frequency of the QVM 50 in the vacuum transfer module VTM when a valve opening position of an automatic pressure control valve APC attached to the exhaust port 40 of the process module PM is fixed at 20 degrees. FIG. 4B illustrates an example of a frequency of the QVM 50 in the vacuum transfer module VTM when a valve opening position of an automatic pressure control valve APC attached to the exhaust port 40 of the process module PM is fixed at 90 degrees.

The slope of the graph in FIG. 4A, “−0.47 Hz/hour,” and the slope of the graph in FIG. 4B, “−0.37 Hz/hour,” are examples of amounts of change in frequency, and indicate deposition rates of a reaction product. The graphs show that as the change in frequency increases, the amount or reaction product attached to the crystal oscillator per unit time also increases. It is noted that the slope of the graph decreases and that the reaction product can be more efficiently removed from the vacuum transfer module VTM when the valve opening position of the automatic pressure control valve APC is great, as illustrated in FIG. 4B, than when the valve opening position of the automatic pressure control valve APC is small, as illustrated in FIG. 4A.

Hence, whether the transfer conditions are preferable or not can be determined by the amount of change in frequency shown by the slope of a graph. In other words, when the amount of change in frequency is less than or equal to the first threshold, the control unit 100 determines that the transfer conditions of the vacuum transfer module VTM is preferable. On one hand, when the amount of change in frequency exceeds the first threshold and is less than or equal to the second threshold, the control unit 100 determines that the transfer conditions of the vacuum transfer module need to be improved. In this case, the control unit 100 can decrease the deposition rate of the reaction product by changing the transfer conditions. On the other hand, when the amount of change in frequency exceeds the second threshold, the control unit 100 determines that the vacuum transfer module VTM needs to be cleaned because the environment inside the vacuum transfer module VTM has become worse and because it is difficult to improve the inside of the vacuum transfer module VTM only by changing the transfer conditions. The cleaning process will be described later.

(Transfer Conditions)

The control unit 100 changes the setting of at least one of a number of transfer parameters, such as the pressure of the vacuum transfer module VTM, the flow rate of the inert gas of the vacuum transfer module VTM, the pressure of the process modules PM1 through PM4, and the flow rate of the inert gas of the process modules PM1 through PM4.

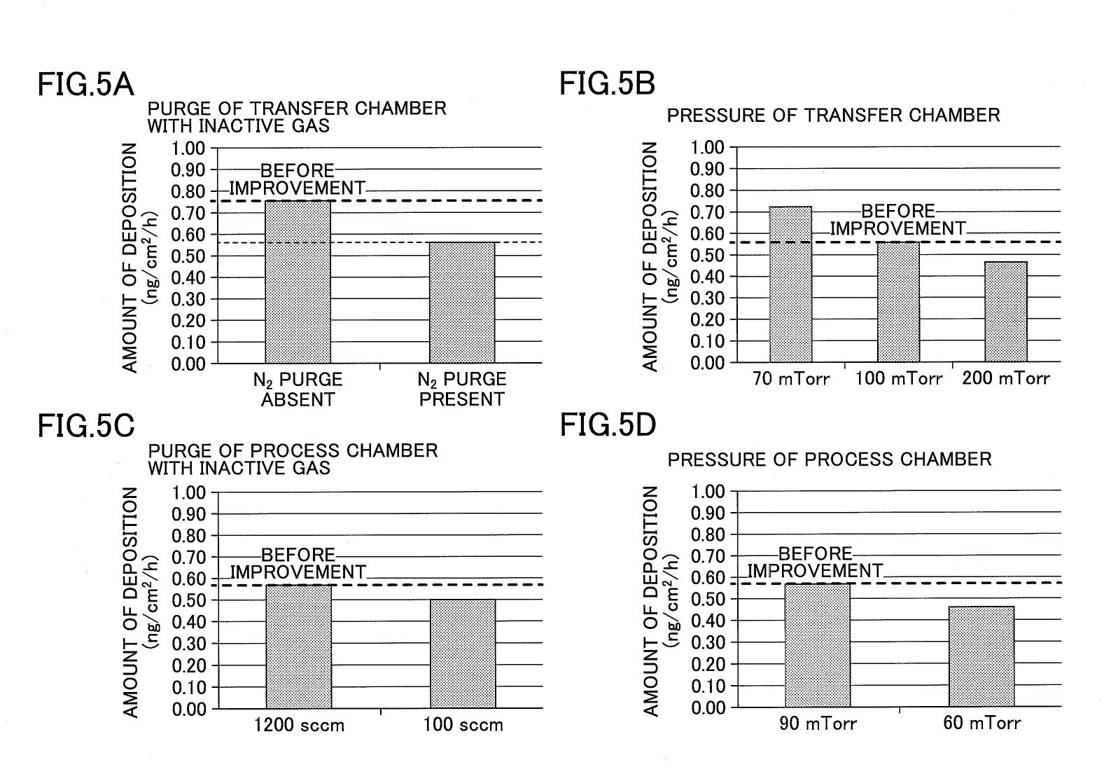

For example, FIG. 5A shows a result of a working example in which an amount of reaction product was measured in the vacuum transfer module VTM when controlling a purge of the vacuum transfer module VTM by an inert gas (N₂). According to the result, when the inert gas (N₂) was supplied to the vacuum transfer module VTM, the amount of reaction product in the vacuum transfer module VTM was reduced and an environment in the vacuum transfer module VTM improved compared to when the inert gas (N₂) was not supplied to the vacuum transfer module VTM, which corresponded to the case before improvement.

FIG. 5B shows a result of a working example of in which an amount of reaction product was measured in the vacuum transfer module VTM when controlling a pressure of the vacuum transfer module VTM. According to the result, when controlling the pressure of the vacuum transfer module VTM so as to become 200 mT (26.66 Pa), the amount of reaction product in the vacuum transfer module VTM was smaller and the environment in the vacuum transfer module VTM was better than when the pressure in the vacuum transfer module VTM was 70 mT (9.33 Pa) and 100 mT (13.33 Pa), which corresponded to the case before improvement.

FIG. 5C shows a result of a working example of in which an amount of reaction product was measured in the vacuum transfer module VTM when controlling a purge of the process module PM by an inert gas (Ar). According to the reuslt, when supplying the inert gas (Ar) to one of the process module PM at a flow rate of 100 sccm, the amount of reaction product was smaller and the environment in the vacuum transfer module VTM was better than when supplying the inert gas (Ar) to the process module PM at a flow rate of 1200 sccm, which corresponded to the case before improvement.

FIG. 5D shows a result of a working example of having measured an amount of reaction product in the vacuum transfer module VTM when controlling a pressure in the process module PM. According to the result, when controlling the pressure of the process module PM so as to become 60 mT (8.00 Pa), the amount of reaction product was smaller and the environment in the vacuum transfer module VTM was better than when controlling the pressure of the process module PM so as to become 90 mT (12.00 Pa), which corresponded to the case before improvement.

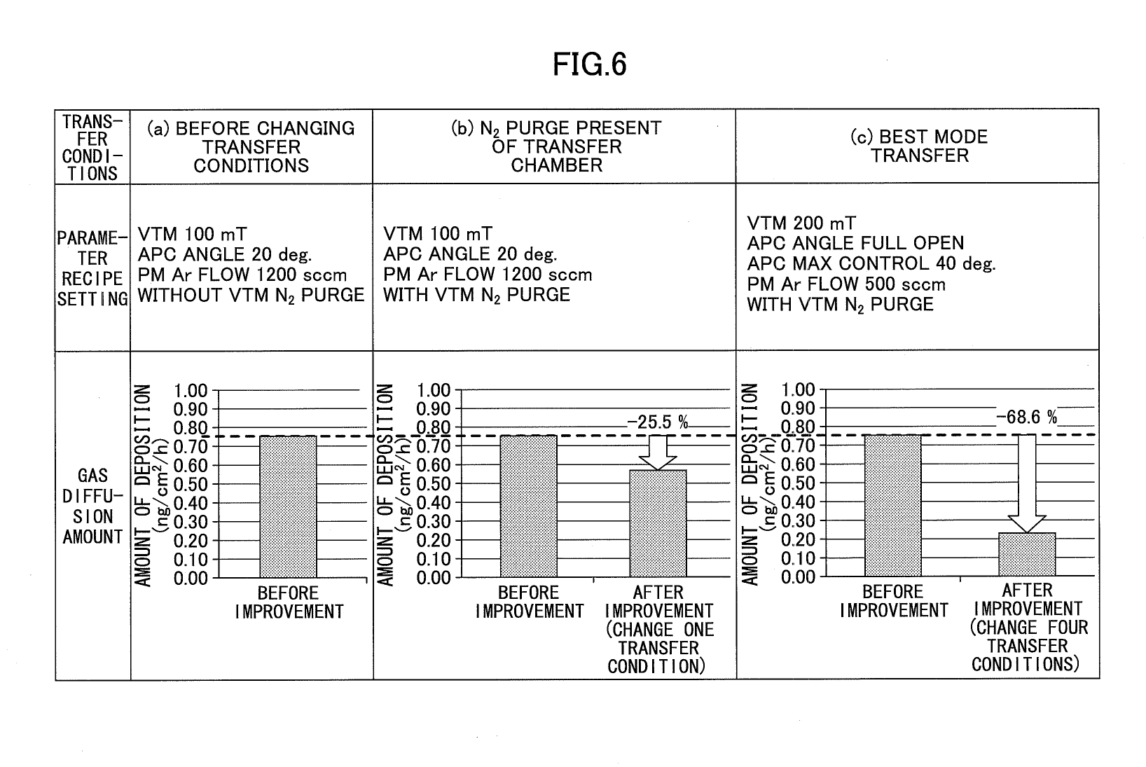

The control unit 100 changes at least one of the above-mentioned transfer conditions. FIG. 6(a) shows the following transfer conditions (1) through (4) before change and an amount of reaction product that has accreted in the VTM.

The transfer conditions before change was as follows.

### (1) Pressure of Vacuum Transfer Module: 100 mT (13.33 Pa)

(2) Valve Opening Position of Automatic Pressure Control Valve: 20 degrees (fixed)
(3) Supply of Inert gas (Ar) to Process Module PM: 1200 sccm

### (4) Supply of Inert gas (N₂) to Vacuum Transfer Module: Absent.

FIG. 6B shows an amount of reaction product when the supply of the inert gas (N₂) to the vacuum transfer module VTM was controlled, which corresponds to the condition (4) that is one of the transfer conditions.

This means that an N₂ purge of the vacuum transfer module VTM was started.

That is, the transfer conditions at this time were as follows.

### (1) Pressure of Vacuum Transfer Module: 100 mT (13.33 Pa)

(2) Valve Opening Position of Automatic Pressure Control Valve: 20 degrees (fixed)
(3) Supply of Inert gas (Ar) to Process Module PM: 1200 sccm

### (4)Supply of Inert gas (N₂) to Vacuum Transfer Module: Present.

By changing the transfer conditions so as to start supplying the inert gas (N₂) to the vacuum transfer module VTM, the amount of reaction product deposited in the vacuum transfer module VTM could be reduced by 25.5% of the amount of reaction product deposited in the status of FIG. 6A, which was performed in the transfer conditions where the inert gas (N₂) was not supplied.

FIG. 6C shows an amount of reaction product when changing all transfer conditions of (1) to (4).

That is, the transfer conditions at this time were the following.

### (1) Pressure of Vacuum Transfer Module: 200 mT (26.66 Pa)

(2) Valve Opening Position of Automatic Pressure Control Valve: 40 degrees (fixed)
(3) Supply of Inert gas (Ar) to Process Module PM: 500 sccm

### (4) Supply of Inert gas (N₂) to Vacuum Transfer Module: Present.

Thus, by changing all of the transfer conditions of (1) through (4), the amount of reaction product deposited in the vacuum transfer module VTM could be reduced by 68.6% of the amount of reaction product deposited in the status of FIG. 6A.

(Cleaning)

In step S16 of FIG. 3, when the amount of change in frequency of the QCM 50 exceeds the second threshold, the control unit 100 performs the cleaning process in step S22.

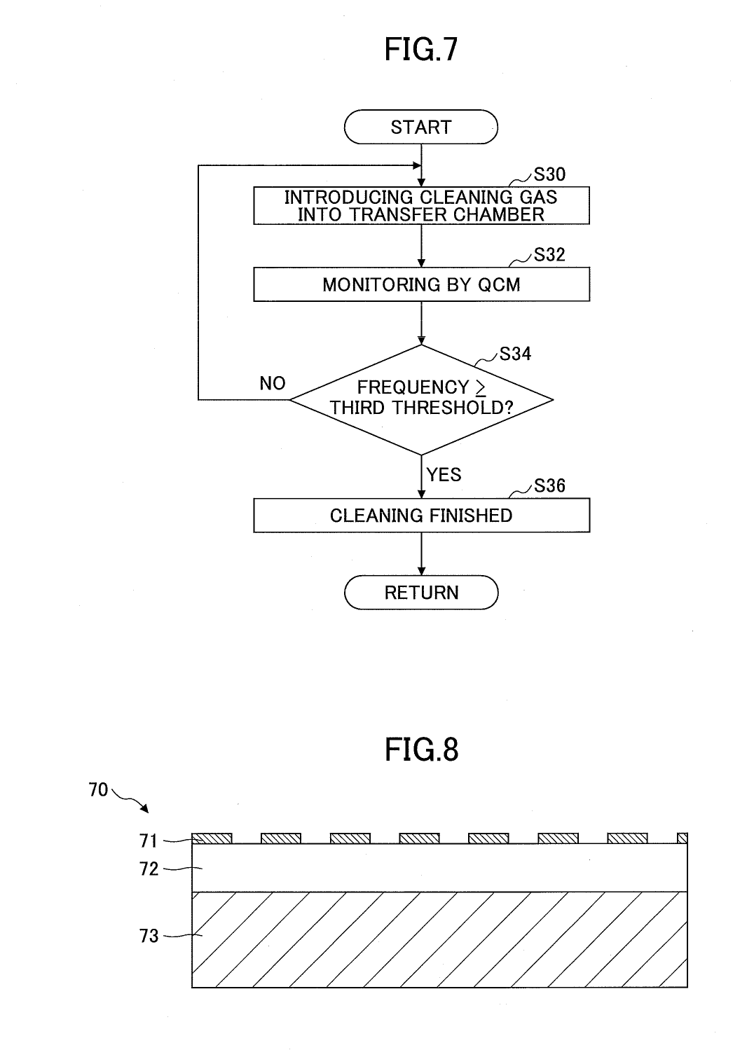

An example of the cleaning process in the vacuum transfer module VTM is described below with reference to a flowchart of FIG. 7. When the cleaning process of FIG. 7 is started, the control unit 100 introduces a cleaning gas (step S30).

Next, the control unit 100 starts monitoring accretion by using the crystal oscillator of the QCM 50 disposed in the vacuum transfer module VTM (step S32). When a plurality of QCMs 50 is disposed in the vacuum transfer module VTM, each oscillator of the plurality of QCMs 50 monitors accretion of the reaction product.

Subsequently, the control unit 100 determines whether the frequency of the crystal oscillator has reached a predetermined three threshold (step S34) When the control unit 100 determines that the frequency of the crystal oscillator does not reach the third threshold, the process returns to step S30, and process steps S30 through S34 are repeated.

In contrast, in step S34, when the control unit 100 determines that the frequency of the crystal oscillator has reached the third threshold, the control unit 100 stops the cleaning (step S36), and ends the present process. Here, for example, the third threshold can be set at such a frequency that the crystal oscillator would have in clean conditions where the reaction product is not deposited inside the vacuum transfer module VTM.

Thus, during the cleaning, end point detection (EPD) of the cleaning can be performed by using the frequency of the crystal oscillator. This makes it possible to optimize a period of time required for the cleaning and to improve throughput.

Although the embodiments have been described by citing an example of the substrate transfer process in the vacuum transfer module VTM, the substrate transfer process can be performed in the load lock modules LLM1 and LLM2 and the loader module LM in a similar manner.

As described above, according to the substrate transfer method of the embodiments, the environment of the vacuum transfer module VTM can be made preferable by two-step automatic control performed by the control unit 100. For example, when an amount of change in frequency of the crystal oscillator exceeds the second threshold (second threshold>first threshold), the control unit 100 determines that it is difficult to make the environment in the vacuum transfer module VTM normal by only changing the transfer conditions, and performs the cleaning process. Thus, the reaction product inside the vacuum transfer module VTM can be removed.

As a result of the cleaning process, when the amount of change in frequency is lower than or equal to the second threshold and higher than the first threshold, the control unit 100 reduces the amount of reaction product inside the vacuum transfer module VTM by changing the transfer conditions. When the amount of change in frequency falls below the first threshold, the control unit 100 causes the wafer W to be transferred while maintaining the present transfer conditions.

In the substrate transfer method according to the embodiments, the control unit 100 may automatically control the transfer conditions to not only reduce the amount of reaction product but also to prevent the throughput from decreasing, further to improve the throughput when possible. For example, it is conceivable that a period of time for supplying a purge gas into the process module PM and the vacuum transfer module VTM, is increased in a plasma process by using O₂ plasma, for example, referred to as asking, and/or an after-treatment of a wafer W processed by using plasma with Ar gas for removing residual charge of the wafer W. In this case, the effect of making the environment in the vacuum transfer module VTM preferable is improved, but the throughput is reduced. Therefore, under conditions in which a rate of change in frequency is slow (i.e., the slope is smallest), in the graphs of FIGS. 4A and 4B, the transfer conditions maybe changed to conditions in which the throughput is unlikely to decrease or likely to increase. In contrast, under the transfer conditions in which a rate of change is fast (i.e., where the slope is greatest, in the graphs of FIGS. 4A and 4B), even if the throughput is reduced, the transfer conditions may be changed to conditions in which the exchange of a gas is facilitated. Thus, the wafer W can be transferred in optimal transfer conditions in which the throughput is considered.

Thus, according to the embodiments of the present invention, an environment of a substrate transfer apparatus can be made preferable.

Although the substrate transfer apparatus and the substrate transfer method have been described above according to the embodiments, the substrate processing apparatus and the substrate processing method of the present invention are not limited to the embodiments. Various modifications and improvements can be made without departing from the scope of the invention. Moreover, the embodiments and modifications can be combined as long as they are not incompatible with each other.

For example, the contamination monitor provided in the vacuum transfer module VTM is not limited to the QCM 50, but another sensor other than the QCM 50 may be used. As illustrated in FIG. 8, a capacitive type sensor 70 may be used as another example of a suitable contamination monitor. The capacitive type sensor 70 can measure the amount of reaction product deposited by measuring capacitance. The capacitive type sensor 70 is configured to include a conducting body 73 that serves as a lower electrode, a non-conducting substance 72, such as a polymer thin film or an aluminum oxide film, provided directly on the conducting body 73, and patterned conducting bodies 71 formed on the non-conducting substance 72. The conducting body 71 serves as an upper electrode. According to the conductive type sensor 70, the amount of reaction product deposited can be measured by monitoring changes in capacitance caused by adhesion and adsorption of matter to the non-conducting substance 72.

Another device can be applied to the process module PM of the semiconductor manufacturing apparatus according to the embodiments of the present invention as well as a capacitively coupled plasma (CCP) device. More specifically, the applicable device includes an inductively coupled plasma (ICP) processing device, a plasma processing device using a radial line slot antenna, a helicon wave excited plasma (HWP) processing device, an electron cyclotron resonance plasma (ECR) processing device. Otherwise, a plasmaless device that performs an etching process or a film deposition process by a reaction gas and heat is also applicable.

Furthermore, in the present specification, although the semiconductor wafer W has been described as an example of the substrate, a variety of substrates used for an LCD (Liquid Crystal Display), a FPD (Flat Pannel Display) and the like, a photomask, a CD substrate, a printed board and the like are available for the substrate.

What is claimed is:

1. A substrate transfer apparatus comprising:
a transfer chamber in which a substrate is transferred; and
a process chamber configured to process the substrate therein; and
a contamination monitor provided in the transfer chamber and configured to detect a contamination condition of the transfer chamber.

2. The substrate transfer apparatus as claimed in claim 1, wherein the contamination monitor is a crystal oscillator.

3. The substrate transfer apparatus as claimed in claim 1,
wherein the transfer chamber includes a first transfer chamber adjacent to the process chamber and a second transfer chamber that is separated from the process chamber by the first transfer chamber; and
the contamination monitor is disposed at least in the first transfer chamber.

4. The substrate transfer apparatus as claimed in claim 1,
wherein the transfer chamber includes a first transfer chamber adjacent to the process chamber and a second transfer chamber that is separated from the process chamber by the first transfer chamber; and
the contamination monitor is disposed in each of the first transfer chamber and the second transfer chamber.

5. The substrate transfer apparatus as claimed in claim 1, wherein the contamination monitor is disposed at at least one of a gate valve provided in the transfer chamber, a ceiling part of the transfer chamber, a movable part of a transfer device provided in the transfer chamber, an exhaust port provided in the transfer chamber, and a corner portion of the transfer chamber.

6. The substrate transfer apparatus as claimed in claim 1, further comprising:
a transfer device configured to transfer the substrate provided in the transfer chamber; and
a control unit configured to control a transfer condition of the substrate in the transfer chamber based on information indicating the contamination condition of the transfer chamber detected by the contamination monitor and to cause the transfer device to transfer the substrate based on the transfer condition.

7. The substrate transfer device as claimed in claim 6, wherein the control unit controls the transfer condition of at least one of a pressure of the transfer chamber, a flow rate of an inert gas in the transfer chamber, a pressure of the process chamber, and a flow rate of an inert gas in the process chamber.

8. The substrate transfer device as claimed in claim 6, wherein the control unit controls cleaning of an inside of the transfer chamber based on the information indicating the contamination condition of the transfer chamber detected by the contamination monitor.

9. The substrate transfer device as claimed in claim 8, wherein the control unit controls an end point of the cleaning of the inside of the transfer chamber based on the information indicating the contamination condition of the transfer chamber detected by the contamination monitor while cleaning the inside of the transfer chamber.

10. A substrate transfer method for transferring a substrate processed in a process chamber through a transfer chamber, the method comprising:
detecting a contamination condition of a transfer chamber by using a contamination monitor provided in the transfer chamber;
controlling a transfer condition of a substrate in the transfer chamber based on information indicating the contamination condition of the transfer chamber detected by the contamination monitor; and
transferring the substrate based on the transfer condition.
